(19) United States
(12) Patent Application Publication
(10) Pub. No.: US 2010/0295608 A1
(43) Pub. Date: Nov. 25, 2010

(54) DEMODULATION METHOD UTILIZING DELAYED-SELF-SAMPLING TECHNIQUE

(76) Inventors: Ming-Jen YANG, Hsinchu City (TW); Hong-Sing KAO, Hsinchu City (TW)

Correspondence Address: Muncy, Geissler, Olds & Lowe, PLLC, 4000 Legato Road, Suite 310, FAIRFAX, VA, 22033, US

(21) Appl. No.: 12/850,113

(22) Filed: Aug. 4, 2010

Related U.S. Application Data
(63) Continuation-in-part of application No. 11/709,888, filed on Feb. 23, 2007.

(51) Int. Cl. H03K 9/04

(52) U.S. Cl. 329/313

(57) ABSTRACT

Rather than using an external sampling clock to perform time-to-digital conversion function, input signal is self-sampled by its own delayed signals. A demodulation method utilizing delayed-self-sampling technique, comprising steps of: obtaining a signal processed by a limiting amplifier as the only input signal required for demodulation; transferring the limiting amplified signal via two paths, by one of which the limiting amplified signal is directly sent to an input end of a delayed-self-sampler, and by the other of which the limiting amplified signal is sent to a delay line for generating and outputting time delayed signals; sampling the limiting amplified signal by time delayed signals from the delay line with delayed-self-sampler to generate a group of sampled data; and converting the group of sampled data by a thermometer-to-binary converter into a group of binary codes, which is input into data decision circuitry to be processed into recovered base-band data. The advantage of demodulation method utilizing delayed-self-sampling technique is the delayed-self-sampler can avoid edge synchronization problem and reduce power consumption.

### CROSS-REFERENCE TO RELATED DOCUMENTS

The present invention is a continuation in part (CIP) to a U.S. patent application Ser. No. 11/709,888 entitled “DEMODULATION METHOD UTILIZING DELAYED-SAMPLING TECHNIQUE” filed on Feb. 23, 2007.

### BACKGROUND OF THE INVENTION

1. Field of the Invention

The present invention relates to a demodulation method utilizing delayed-self-sampling technique and, more particularly, to a method utilizing delayed-self-sampling technique for time-to-digital conversion, phase demodulation, and frequency demodulation, by which the data processing speed is increased and the complexity, power consumption, and cost are reduced.

2. Description of the Prior Art

In a general communication system, there are many demodulation methods used for signals modulated by angle (frequency or phase) into data. The most commonly used methods usually utilize a phase-locked loop (PLL) or a quadrature detector. And a frequency counter is also commonly used if the modulation speed is slow enough.

Frequency phase-locked loop is a non-linear closed-loop system, and the optimization of the system's characteristics is often confined by the stability of a feedback loop for the system itself has at least one integrating term. Besides, digital phase-locked loop needs a high frequency clock much higher than an input signal. The use of both will consume too much power to be used in a battery-powered system.

A commonly used quadrature detector has a tuned phase-shift network for generating a frequency dependent phase shift to a signal. The quadrature detector is also a non-linear circuit, so its designation needs a tradeoff between the sensitivity and linearity. Besides, the phase shift circuit or other components used in a quadrature detector are not cheap. It will be difficult to use the quadrature detector because of the individual variation and the dependence on temperature or process.

In a conventional demodulation method for discontinuous timing frequency modulated signals, the instantaneous amplitudes of angle-modulated signals are sampled by an analog-to-digital converter first, then digitally delayed, and operated via some mathematical operations (division) to obtain the demodulated data finally. However, the method is disadvantageous because it is necessary to use an analog-to-digital converter of high speed and high power consumption, and division of mathematic operation, which are not suitably used in a wireless communication system, which demands low power consumption.

The principle of a conventional method using a digital frequency counter for capturing data is to use the digital frequency counter having a reference oscillator therein and a counter to measure two successive zero-crossing time intervals. This method needs a high frequency clock, so it usually consumes a lot of power and is not suitably used in hand-held devices.

FIG. 1 shows a conventionally used circuit using similar operation principle mentioned above. This method also needs a high frequency clock. Advantage of this method is that the signals to be demodulated can be directly transformed into digital data by using relevant zero-crossing information without the need of using an analog-to-digital converter.

Many interpolation techniques can be used to increase the resolution of time interval measurement while a low frequency clock or even no clock needs to be adopted. FIG. 2 shows a conventional method using an interpolator composed of tapped delay lines and having increased resolution of time interval measurement without increasing power consumption. The tagged delay lines are used for delaying the edge of the signals to be measured, and a cycle time can be measured by delaying an edge and a next edge. This method is impractical in two aspects. First, a too much long delay line will be needed if the frequency deviation is very low (such as +−5 kHz in a wireless system with an intermediate frequency of 455 khz). For example, a tagged delay line with 1000 levels is able to provide +−10 degrees of quantization in modulation. However, in recent semiconductive manufacturing, necessary linearity in use will be achieved if such a long delay line doesn't include a trimming circuit. Second, under this structure, the operation principle of its coincidence logic circuit is based on the assumption that the pulse width in the delay line is a constant. But it is very difficult to achieve the requirement of the assumption, especially when the delay must be controllable.

Moreover, in a conventional demodulation method using tapped delay lines together with a clock signal, frequency modulated signals are propagated via the delay lines composed of complementary metal-oxide semiconductor buffers. The clock signals here are used for latching the phase of each clock rising edge. The data from the measurement of two successive latching phases can be used to interpolate the time when signals are already in halfway of the delay line. Because interpolation operation is used under this structure, it is unnecessary to calibrate the unit delays used for forming a delay line to a certain value. However, two disadvantages make this method still impractical. First, the delay line will be necessarily very long for the need that the total delay must be larger than at least two clock cycles. Secondly, the measurable range of the interpolator is not constant, so that when detecting each zero-crossing point, at least two additions and one division have to be adopted. The hardware required to execute these immediate mathematical operations and a large interpolator make this method impractical.

In another conventional demodulation method using frequency counter together with a short (8 levels totally) interpolating delay line, the realization mode or the calibration method of the interpolator are not mentioned. Besides, in the figure, a stable high frequency oscillator is suggested to adopt, but it is usually impractical. In order to obtain appropriate resolution, the input signals are rectified to double their frequency deviation, and then the input signals are converted into low frequency via frequency division, and the cycle time can be measured. Although it will become easier for time measurement if the frequency is divided by M-fold, a lot of relevant information of the signals will be lost (for only one detection per M cycles), especially when the signals are noisy. The performance of this method is even worse than the system measuring two successive zero-crossing time intervals.

In a conventional digital demodulation method for digitally demodulating frequency-modulated or phase-modulated signals via time interval measurement, there is no need of a high-frequency oscillator and the delay lines are not necessarily extreme long. Besides, the feedback loop in this method excludes the input signals, so that it will not be confined by the stability. However, this method needs an extra reference frequency, which is usually larger than frequency of the input signal at least one order. Moreover, it also needs a delayed-locked loop for fixing the unit delay of the delay line within a certain range. These extra circuits will increase the complexity, the power consumption, and the cost of the system and these characteristics are important for a battery-powered system. Furthermore, this method can only be used in a system in which the frequency deviation is much smaller than the intermediate frequency, that is, the frequency deviation is about one-hundredth the intermediate frequency of the system. If not, the whole system must be adjusted.

Rather than using an external sampling clock to perform time-to-digital conversion function, input signal is self-sampled by its own delayed signals to solve the above-stated problems to provide a demodulation method using a delayed-self-sampling technique which requires only an input signal and needs no external clock for frequency or phase demodulation, the inventor had the goal to try and develop the present invention after long and difficult research to solve the problem of disordered space.

### SUMMARY OF THE INVENTION

The main object of the present invention is to provide a demodulation method using a delayed-self-sampling technique, by which no external sampling clock is required for time-to-digital conversion and can avoid edge synchronization problem.

In order to achieve the above object, the present invention provides a demodulation method utilizing delayed-self-sampling technique, comprising steps of: obtaining a signal processed by a limiting amplifier as the only input signal required for demodulation; transferring the limiting amplified signal via two paths, by one of which the limiting amplified signal is directly sent to an input end of a delayed-self-sampler, and by the other of which the limiting amplified signal is sent to a delay line which composes of a coarse and fine delay lines for generating and outputting time delayed signals; sampling the limiting amplified signal by time delayed signals from the delay line with delayed-self-sampler to generate a group of sampled data; and converting the sampled data by a thermometer-to-binary converter into a group of binary codes, which is input into a data decision circuitry to be processed into recovered base-band data.

The following detailed description, given by way of examples and not intended to limit the invention solely to the embodiments described herein, will best be understood in conjunction with the accompanying drawings.

### BRIEF DESCRIPTION OF THE DRAWINGS

FIG. 1 is a circuit diagram of a conventional method using a digital frequency counter to capture data.

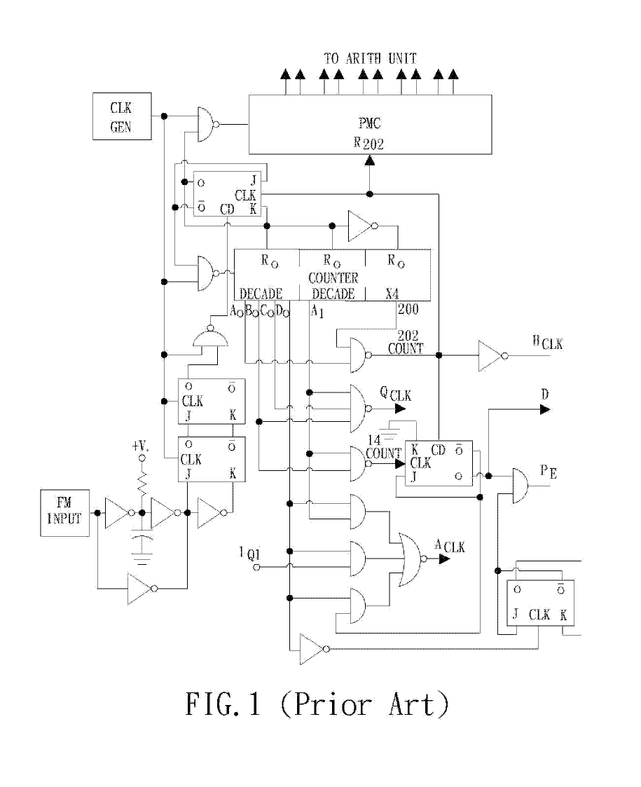

FIG. 2 is a circuit diagram of a conventional method using an interpolator composed of tagged delay lines for increasing the resolution of time interval measurement without a lot of power consumption.

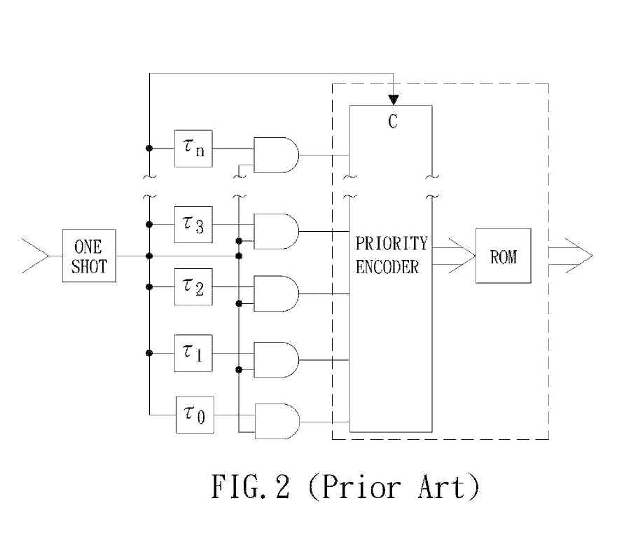

FIG. 3 is a flow chart of the present invention.

FIG. 4 is a block diagram of the present invention.

FIG. 5 is a block diagram illustrating an embodiment of the delay line and delayed-self-sampler, such as may be incorporated in the embodiment illustrated in FIG. 4

FIG. 6 is a timing diagram of input signal after being limiting amplified, coarse delayed and fine delayed by a delay line in the present invention.

FIG. 7 is a schematic diagram illustrating input and delayed-self-sampled waveform according to the present invention.

FIG. 8 is a schematic diagram illustrating thermometer-to-binary conversion of input waveform according to the present invention.

FIG. 9 is a schematic diagram illustrating the way of data decision according to the present invention.

### DETAILED DESCRIPTION OF THE PREFERRED EMBODIMENTS

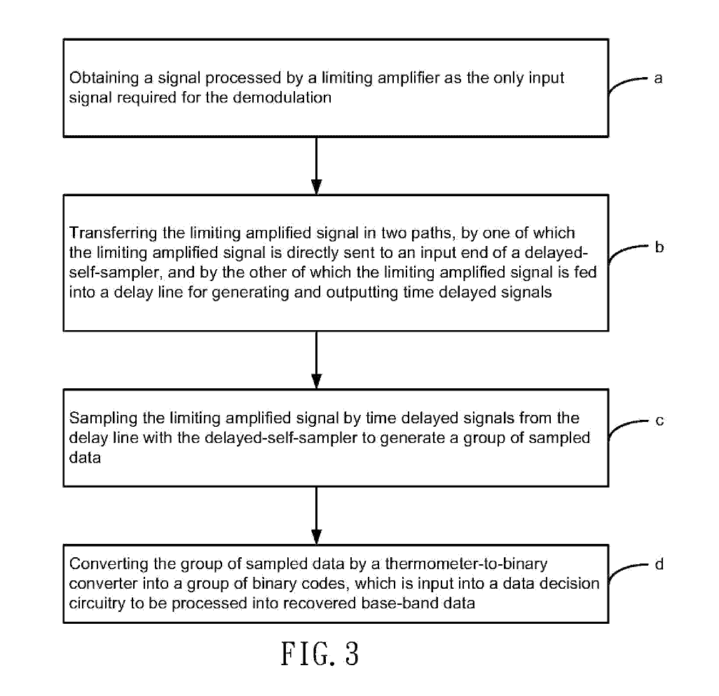

FIG. 3 shows a flow chart of a demodulation method using delayed-self-sampling technique according to the present invention. As shown in FIG. 3, the method comprises steps of:

a. obtaining a signal processed by a limiting amplifier as the only input signal required for demodulation;

b. transferring the limiting amplified signal via two paths, by one of which the limiting amplified signal is directly sent to an input end of a delayed-self-sampler, and by the other of which the limiting amplified signal is sent to a delay line for generating and outputting time delayed signals;

c. sampling the limiting amplified signal by time delayed signals from the delay line with the delayed-self-sampler to generate a group of sampled data; and

d. converting the group of sampled data by a thermometer-to-binary converter into a group of binary codes, which is input into a data decision circuitry to be processed into recovered base-band data.

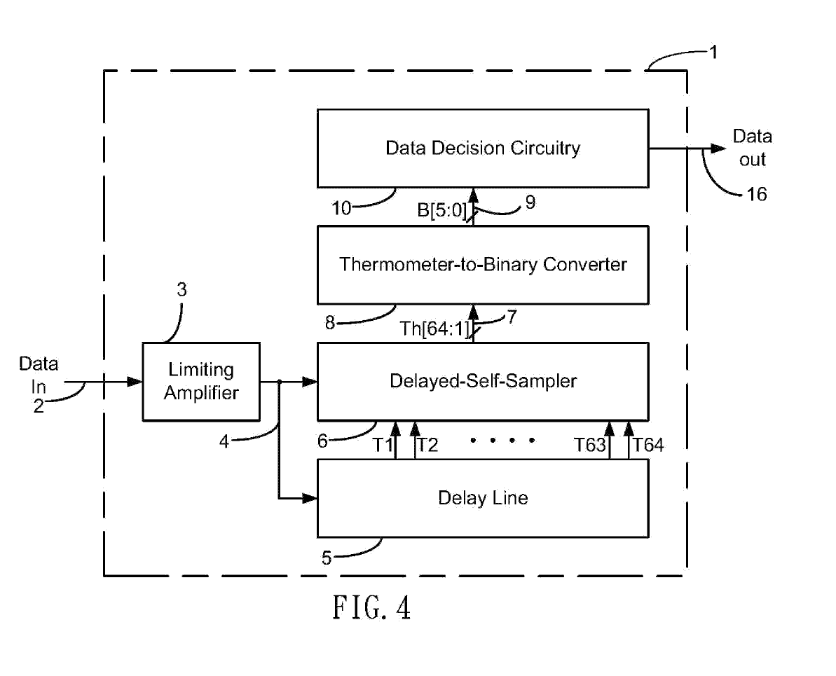

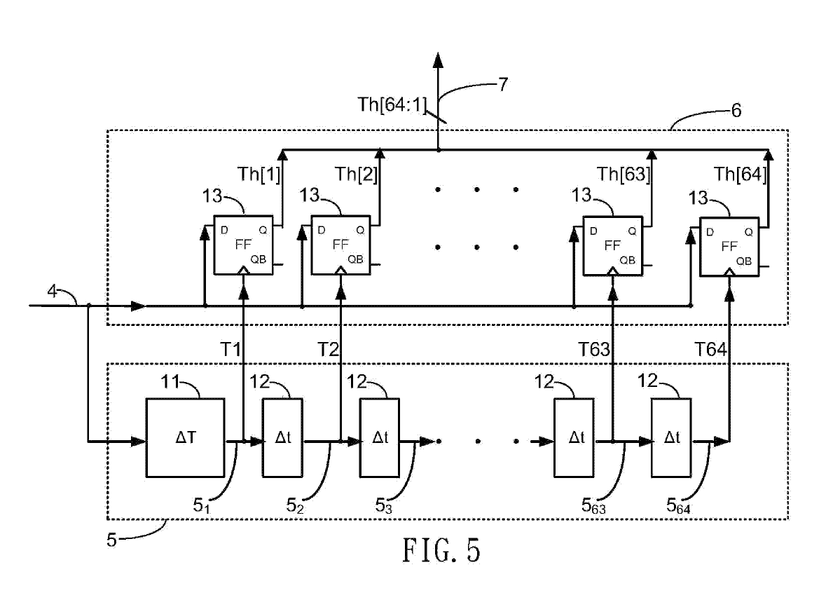

When in practice, as shown in FIGS. 3, 4 and 5, the present invention includes a limiting amplifier 3, a delay line 5 which composes of a coarse delay line 11 and fine delay lines 12, a delayed-self-sampler 6, a thermometer-to-binary converter 8, and a data decision circuitry 10. The signal processed by the limiting amplifier 3 is used as the only input signal in the present invention. And the limiting amplified signal 4 is transferred via two paths, that is, the limiting amplified signal 4 will be transferred via the delay line 5 or directly transferred to the input end of the delayed-self-sampler 6 without passing through the delay line 5. FIG. 5 illustrates an embodiment of the delay line and delayed-self-sampler, such as may be incorporated in the embodiment illustrated in FIG. 4. As shown in FIG. 5, after the limiting amplified signal by the way of the coarse delay line 11 and passing through the fine delay line 12, different timing delayed signals 5₁ through 5₆₄ will be generated and outputted. These different timing delayed signals T1 to T64 will be used as sampling clocks of self-sampling devices 13 in the delayed-self-sampler 6. After the limiting amplified signal 4 is self-sampled by the delayed-self-sampler 6, a group of sampled data 7, Th[64:1] is generated and can be converted into a group of binary codes 9, B[5:0] by a thermometer-to-binary converter 8. Then the group of binary codes 9, B[5:0] is input into the data decision circuitry 10 to be processed into recovered base-band data 16.

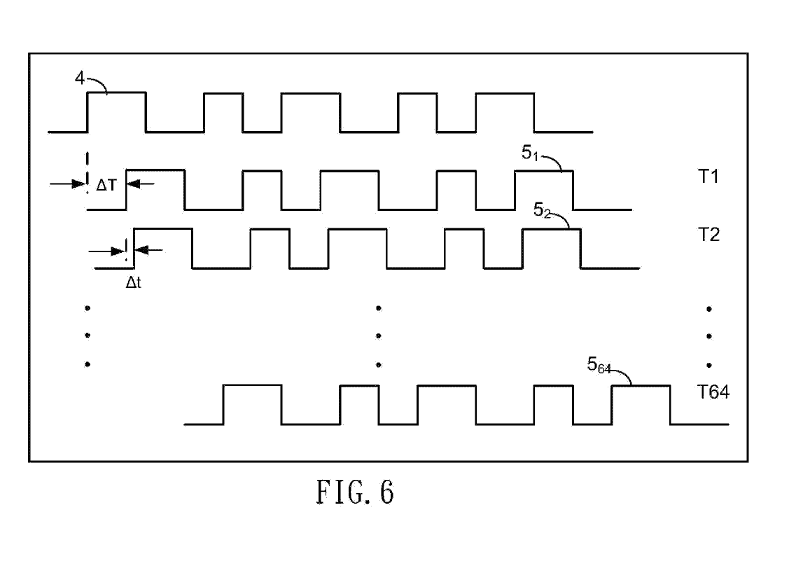

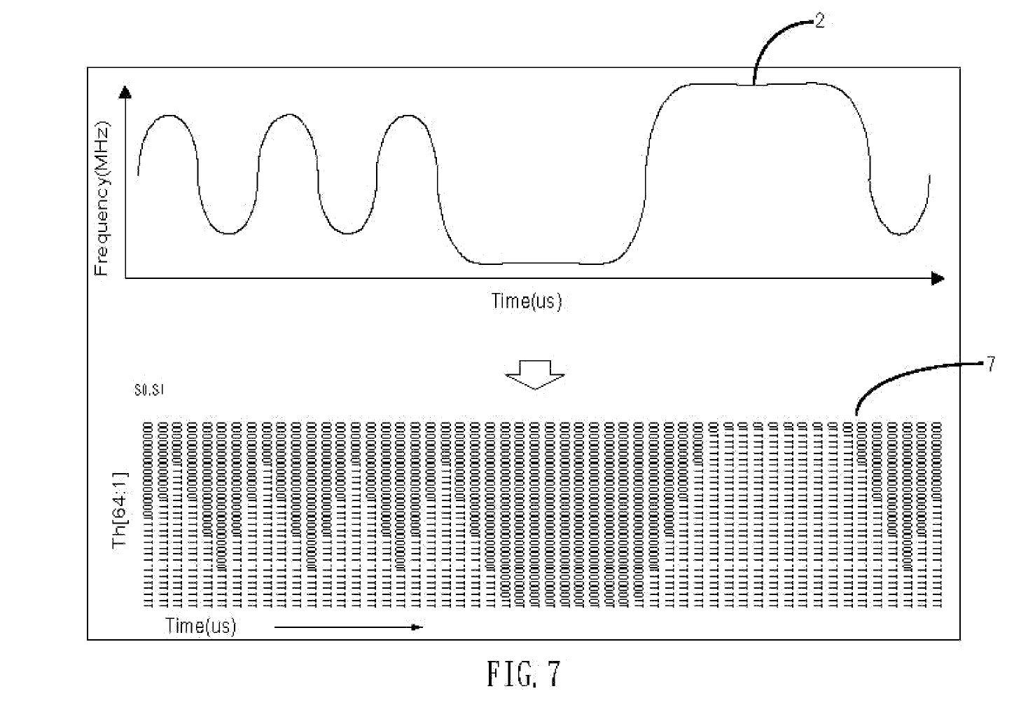

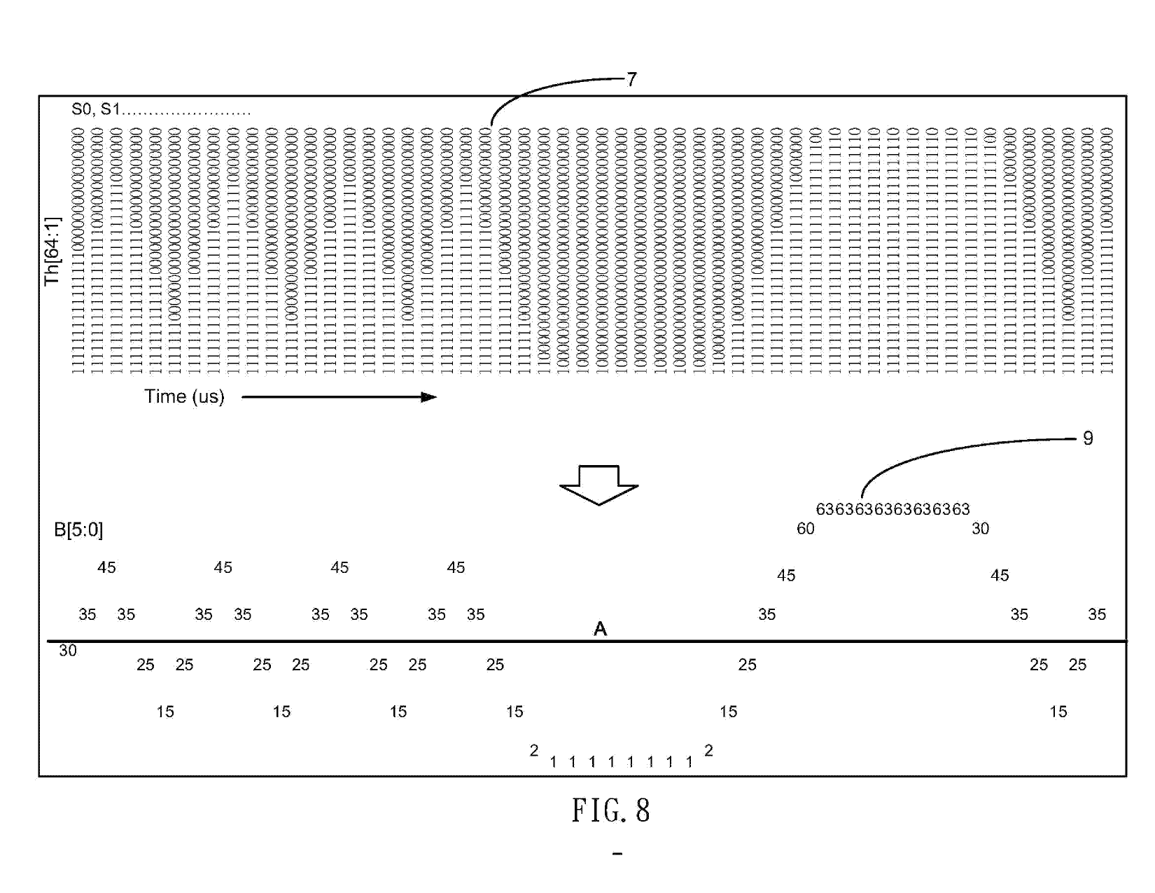

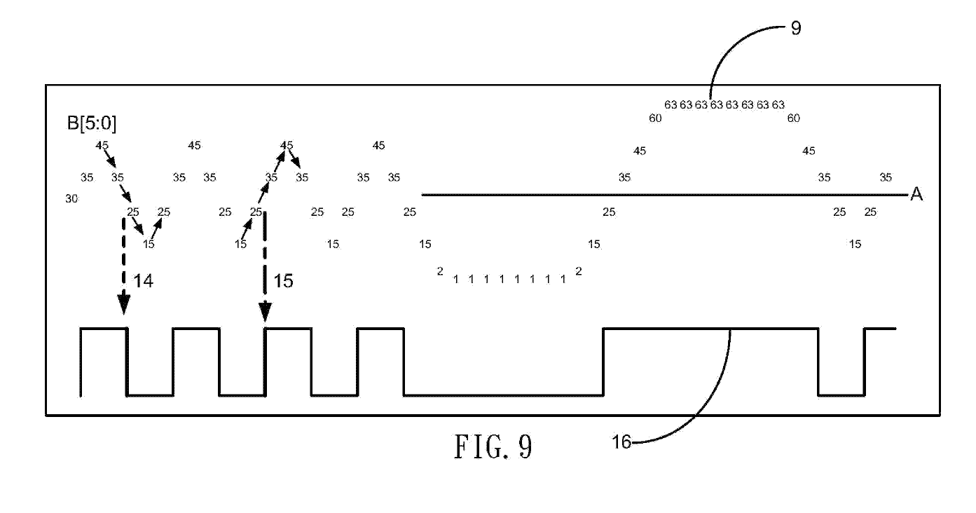

FIG. 6 shows the timing diagram of input signal after being limiting amplified , coarse-delayed and fine-delayed by the delay line 5 according to the present invention. As shown in FIG. 6, the total delay of the delay line 5 (ΔT+63 Δt) is approximately equal to the cycle time of the intermediate frequency of input signal 2 and needs no high precision in the present invention. The operation concept is that, if the base-band signal is “0”, the result after being self-sampled will contain more digits of “0”; if the base-band signal is “1”, the result after being self-sampled will contain less digits of “0”.FIGS. 7 and 8 are waveform diagrams showing the input signal processed via delayed-self-sampling and thermometer-to-binary conversion. Besides, FIG. 9 shows a method for data decision according to the present invention. The method for data decision takes advantage of preamble (such as 01010 or 10101) in general communication protocol and differentiation method to find out the rising (15) and falling edge (14) of the data, by which the threshold A can be obtained for determining whether the value is 0 or 1. Thereby, the delayed-self-sampling technique in accordance with the present invention can perform demodulation without using an external sampling clock, delayed-locked loop to fix the unit delay of the delay line within a certain range, closed-loop, and considering the problem that the frequency deviation, compared with the intermediate frequency, cannot be too high. Likewise, the delayed-self-sampling technique in accordance with the present invention only requires the limiting amplified signal as the only input signal for demodulation and needs no extensive circuitry, it lends itself, the data processing speed can be increased and the complexity, power consumption, and the cost of the system can be reduced.

Accordingly, as disclosed in the above description and attached drawings, the present invention can provide a demodulation method utilizing delayed-self-sampling technique with no needs of external oversampling clock for time-to-digital conversion and can avoid edge synchronization problem.

It should be understood that many modifications, variations, substitutions, changes or equivalents could be made from the teaching disclosed above by those skilled in the art, without departing from the spirit and scope of the invention as defined in the appended claims.

We claim:

1. A demodulation method utilizing delayed-self-sampling technique, comprising steps of
a. obtaining a signal processed by a limiting amplifier as the only input signal required for demodulation;
b. transferring the limiting amplified signal via two paths, by one of which the limiting amplified signal is directly sent to an input end of a delayed-self-sampler, and by the other of which the limiting amplified signal is sent to a delay line for generating and outputting time delayed signals;
c. sampling the limiting amplified signal by time delayed signals from the delay line with the delayed-self-sampler to generate a group of sampled data; and
d. converting the group of sampled data by a thermometer-to-binary converter into a group of binary codes, which is input into a data decision circuitry to be processed into recovered base-band data.

2. The demodulation method utilizing delayed-self-sampling technique as claimed in claim 1, wherein the delay line further comprises a coarse delay line and fine delay lines, and different time delayed signals are generated after the limiting amplified signal passing through the coarse delay line and the fine delay lines.

3. The demodulation method utilizing delayed-self-sampling technique as claimed in claim 1, wherein delayed-self-sampler uses the different time delayed signals from the delay line as sampling clock to self-sample the limiting amplified (un-delayed) signal to perform the delayed-self-sampling.

4. The demodulation method utilizing delayed-self-sampling technique as claimed in claim 1, wherein the delayed-self-sampler further includes a group of self-sampling devices with an un-delayed signal as its input and delayed version of signals as its sampling clock.
